(19) United States
(12) Patent Application Publication
(10) Pub. No.: US 2014/0266290 A1
(43) Pub. Date: Sep. 18, 2014

(54) PROCESS DETECTION CIRCUIT

(71) Applicants: Bhavin Odedara, Bangalore (IN); Deepak Pancholi, Bangalore (IN); Prasad Naidu, Bangalore (IN)

(72) Inventors: Bhavin Odedara, Bangalore (IN); Deepak Pancholi, Bangalore (IN); Prasad Naidu, Bangalore (IN)

(21) Appl. No.: 13/897,581

(22) Filed: May 20, 2013

(30) Foreign Application Priority Data
Mar. 14, 2013 (IN) 1110/CHE/2013

(51) Int. Cl. G01R 31/26

(52) U.S. Cl. CPC G01R 31/2607
USPC 324/762.01

(57) ABSTRACT

A process detection circuit can detect process information in both PMOS and NMOS devices without external components or trimming. The process detection circuit may be able to identify process information on a gate-source voltage (V_{GS}) that represents process effects. Identified process information may be used to optimize system on a chip (SoC) operation.

### PRIORITY CLAIM

This application relates claims priority to New Ordinary Indian Patent Application No. 1110/CHE/2013 filed on Mar. 14, 2013, entitled “PROCESS DETECTION CIRCUIT”, the entire disclosure of which is hereby incorporated by reference.

### TECHNICAL FIELD

This application relates generally to a process detection circuit. More specifically, this application relates to detecting process characteristics for different MOS devices without using external components or a trimming mechanism.

### BACKGROUND

Advances in integrated circuit (IC) technologies have resulted in decreasing the size of devices used to fabricate circuitry. Along with process geometries shrinking, there is an increase in functionality that is integrated into a system on a chip (SoC) design. Further, there remains a need for higher data transfer rates. The rapid shrinking of feature sizes in ICs has not been accompanied by corresponding scaling of geometric tolerances. Accordingly, circuit performance may be more sensitive to uncontrollable statistical process variations. In particular, there may be an increase in variations of design parameters like delay and power, which results in system level challenges in terms of power management and clock management.

Process, Voltage, and Temperature (PVT) monitors may be included in the SoC design. Existing solutions for detection of process may include a ring oscillator based process detection that only indicates the combined effects of NMOS and PMOS. In other words, PMOS and NMOS process characteristics are not distinguished separately. Another existing solution may include generating accurate current using a band-gap reference that requires an extra IO PAD and an external precision resistor.

### SUMMARY

The process detection circuit can detect process information in both PMOS and NMOS devices and other devices like BJT and diode without external components or trimming. The process detection circuit may be able to identify process information (e.g. slow, fast and typical) based on a gate-source voltage (V_{GS}) that represents process effects. Identified process information may be used to optimize SoC operation by adjusting a supply level, to optimize slew rate of IO or any other parameters of the circuit according to process characteristics to meet the desired throughput requirement with optimum power consumption.

### BRIEF DESCRIPTION OF THE DRAWINGS

FIG. 1 is a process, voltage, temperature (PVT) detector.

FIG. 2 is a functional block diagram of a process detection circuit for an NMOS device.

FIG. 3 is a functional block diagram of a process detection circuit for a PMOS device.

FIG. 4 is a process detection circuit for an NMOS device for use with an error amplifier.

FIG. 5 is a process detection circuit for a PMOS device for use with an error amplifier.

FIG. 6 is an example of multiplexer circuitry for the detection circuits and an error amplifier.

FIG. 7 is an error amplifier.

FIG. 8 is an chart of NMOS process detection in different corners.

FIG. 9 is an chart of PMOS process detection in different corners.

### BRIEF DESCRIPTION OF THE PRESENTLY PREFERRED EMBODIMENTS

FIG. 1 is a process, voltage, temperature (PVT) detector 100. The PVT detector 100 includes a process detector circuit 102, a voltage detector circuit 104, and one or more temperature sensors circuit 106. The detector circuits provide an output voltage to an Analog-to-Digital (ADC) converter 108. The ADC 108 may be a high-resolution ADC that is used to detect any variations of input voltage for generating a digital output to be used to trim different circuits in a SoC. For example, the charts in FIGS. 8-9 may be presented as a digital output that is used to identify variations.

The process detector circuit 102 may be used to identify process information or process characteristics. The process information may be used to trim the different parameters inside the sub-blocks of SoC to control variations within an optimum range. In particular, process information may be used to optimize SoC operation by adjusting a supply level according to process characteristics to meet the desired throughput requirement with optimum power consumption. In other words, there is a lowering of supply voltage for FF process and an increase for SS process as compared to TT process, which are further described below with respect to FIGS. 8-9. Process information may also be used to optimize SoC operation by adjusting a size of a transceivers/IO's to satisfy a required drive strength (rise or fall time).

The process detector circuit 102 may include process detectors for multiple devices 110. The process detectors for multiple devices 110 may be NMOS and PMOS devices including input/output (IO) (3.3 volt (V), 1.8V, 1.2V), core (high voltage (HVT), standard voltage (SVT), low voltage (LVT)) devices, or extended to a diode or bipolar junction transistor (BJT) in other embodiments. In particular, FIG. 2 illustrates a functional block diagram of process detection circuit for an NMOS device, while FIG. 3 illustrates a functional block diagram of process detection circuit for a PMOS device. The process detectors for multiple devices 110 include a process detection circuit for an NMOS device as shown in FIG. 4, and a process detection circuit for a PMOS device as shown in FIG. 5.

The process detector circuit 102 further includes both a multiplexer (MUX) and error amplifier as in block 112. The MUX 112 of the process detector circuit 102 is illustrated in FIG. 6. The error amplifier 112 of the process detector circuit 102 is illustrated in FIG. 7.

As described, a process detection circuit 102 of PVT detector 100 detects process information for multiple devices like PMOS/NMOS etc. The information may be used to account for deviations in the semiconductor fabrication process. Process information may also be referred to as process characteristics or process variation. In particular, process information may include variations of process parameters, which may include impurity concentration densities, oxide thicknesses and diffusion depths. The variations may result from non-uniform conditions during diffusions of the impurities, which may introduce variations in the sheet resistance and transistor parameters such as threshold voltage. Accordingly, there may be variations in the dimensions of the devices that result from the limited resolution of the photolithographic process. In one embodiment, process information may include a percentage variation in a performance calculation. Process variations may also be due to variations in the manufacture conditions such as temperature, pressure and dopant concentrations. The ICs may be produced in lots and the electrical properties in different lots may vary. Further, the transistors may have different transistor lengths, which may modify the propagation delay. The process detection circuit 102 described herein provides a mechanism for detecting variations in the process information by measuring the V_{GS} voltage value as further described with respect to the circuits illustrated in FIGS. 2-3.

The circuits described below may include a variety of different transistors including MOS transistors. Metal oxide semiconductor (“MOS”) may refer to the physical structure of certain field effect transistors, having a metal gate electrode placed on top of an oxide insulator, which in turn is on top of a semiconductor material. Complementary metal oxide semiconductor (“CMOS”) is a technology for constructing integrated circuits. CMOS may be used in a variety of digital logic circuits and may also be used in microprocessors, microcontrollers, static RAM, and memory devices, such as flash drives. CMOS technology may be used for analog circuitry, including image sensors, data converters, and/or transceivers for different types of communication. CMOS circuits may utilize p-type and n-type metal oxide semiconductor field-effect transistors (“MOSFETs”) to implement logic gates and other digital circuits found in computing and signal processing equipment. Typical commercial CMOS products may be integrated circuits composed of millions of transistors of both types on silicon. These devices may be referred to as chips, die, or dies. CMOS circuits are used to implement logic gates with p-type and n-type MOSFETs to create paths to the output from either the voltage source or ground. When a path to the output is created from the voltage source, the circuit is said to be pulled up. The other circuit state occurs when a path to output is created from ground and the output pulled down to the ground potential. The devices or transistors used for the circuits below may include N-type metal oxide-semiconductor (“NMOS”) or P-type metal oxide-semiconductor (“PMOS”). NMOS logic utilizes n-type metal oxide-semiconductor field effect transistors (“MOSFETs”) to implement logic gates and other digital circuits. PMOS logic utilizes p-type MOSFETs to implement logic gates and other digital circuits. In one example, the circuit may be suitable for use with a non-volatile memory system or may also apply to a number of different environments and uses. The system may be utilized with any number of types of host devices including cellular telephones, smartphones, digital cameras, personal digital assistants, mobile computing devices, tablets, laptops, netbooks, non-mobile computing devices, audio/mp3 players, video players, and other devices.

FIG. 2 is a process detection circuit for an NMOS device. The device under test (DUT) 202 is the device at which the V_{GS} voltage is tested. The output voltage V(PDET_OUT_N) {also identified as V_{PDET} or V(PDET_OUT_NMOS)} can be made equal to the V_{GS} voltage for identifying process variations. There are effectively three arms for this circuit corresponding to the three identified currents I₂, and I₃. The I₁ current is for the DUT 202. The I₂ current corresponds to an arm with a first resistor R₁. The I₃ current corresponds to an output arm that includes a second resistor R₂ along with the output. The resistors R₁ and R₂ have the same resistance so R₁=R₂. The high gain error amplifier 204 results in the voltage at node A 206 being equal to the voltage at node B 208, such that V(A)=V(B). The high-gain error amplifier 204 and cascode current mirror structures (e.g. the top six PMOS transistors in FIGS. 4 & 5) may be used to minimize the errors due to mismatched currents into these arms, such that I₁=I₂=I₃.

As illustrated, a current I₂ equivalent to V_{GS}/R₁ is generated. A mirrored current I₃ is dumped into another resistor R₂ to effectively create V_{PDET}=V_{GS}*(R₂/R₁). The equations for this process are:

V(PDET_OUT_{—}N)=I₃*R₂

I₂=V_{GS}/R₁

V(PDET_OUT_{—}N)=(V_{GS}/R₁)*R₂{substituting I₃ with I₂ because I₁=I₂=I₃}

V(PDET_OUT_{—}N)=V_{GS}{since R₁=R₂}

The R₂/R₁ mechanism cancels out current variations due to process dependence of resistor variation, so V(PDET_OUT_N) exhibits process dependent variation of only NMOS device. As further described below with respect to FIG. 8, one example of the output and measurements for identifying this variation may have an approximately 150 millivolts (mV) to 200 mV variation in V(PDET_OUT_N) for process variations. A high-resolution ADC, such as ADC 108 in FIG. 1, may be used to detect V_{PDET} output variation and generate a digital output that can be used to trim the different circuits.

FIG. 3 is a process detection circuit for a PMOS device. In particular, FIG. 3 illustrates a circuit that detects process variations in PMOS devices, as compared with FIG. 2, which illustrates a circuit that detects process variations in NMOS devices. The device under test (DUT) 302 is the device at which the V_{GS} voltage is tested. The output voltage V(PDET_OUT_P) {also identified as V(PDET_OUT_PMOS)} can be made equal to the V_{GS} voltage for identifying process variations. There are effectively three arms for this circuit corresponding to the three identified currents I₁, I₂, and I₃. The I₁ current is for the DUT 302. The I₂ current corresponds to an arm with a first resistor R₁. The I₃ current corresponds to an output arm that includes a second resistor R₂ along with the output. The resistors R₁ and R₂ have the same resistance so R₁=R₂. The high gain error amplifier 304 results in the voltage at node A 306 being equal to the voltage at node B 308, such that V(A)=V(B). The high-gain error amplifier 304 and cascode current mirror structures may be used to minimize the errors due to mismatched currents into these arms, such that I₁=I₂=I₃.

As illustrated, a current I₂ equivalent to V_{GS}/R₁ is generated. A mirrored current I₃ is dumped into another resistor R₂ to effectively create V(PDET_OUT_P)=V_{GS}*(R₂/R₁). The equations for this process are:

V(PDET_OUT_{—}P)=I₃*R₂

I₂=V_{GS}/R₁

V(PDET_OUT_{—}P)=(V_{GS}/R₁)*R₂{substituting I₃ with I₂ because I₁=I₂=I₃}

V(PDET_OUT_{—}P)=V_{GS}{since R₁=R₂}

The R₂/R₁ mechanism cancels out current variations due to process dependence of resistor variation, so V(PDET_OUT_P) exhibits process dependent variation for the PMOS device. As further described below with respect to FIG. 9, one example of the output and measurements for identifying this variation may have an approximately 150 millivolts (mV) to 200 mV variation in V(PDET_OUT_P) for process variations. A high-resolution ADC, such as ADC 108 in FIG. 1, may be used to detect this variation and generate a digital output that can be used to trim the different circuits.

FIG. 4 is an example of process detection circuit for an NMOS device for use with an error amplifier. FIG. 5 is an example of process detection circuit for a PMOS device for use with an error amplifier. FIG. 6 is an example of MUX circuitry for the detection circuits of FIGS. 4-5 and an error amplifier. FIG. 7 is an error amplifier. The NMOS process detector 400 of FIG. 4 and the PMOS process detector 500 of FIG. 5 utilize the analog MUX from FIG. 6 to give a process detection output to the error amplifier 700 in FIG. 7. In addition, process detectors for other MOS (e.g. core voltage MOS devices) or BJT or diode may be utilized.

The NMOS process detector 400 of FIG. 4 includes the V_{GS} for an NMOS device as VGS_N 402. The output is shown as PDET_Out_N. The PMOS process detector 500 of FIG. 5 includes the V_{GS} for a PMOS device as VGS_P 502. The output is shown as PDET_Out_P. In one embodiment, the NMOS process detector 400 along with error amplifier may be the same as or interchanged with the NMOS process detector 200 of FIG. 2 and the PMOS process detector 500 along with error amplifier may be the same as or interchanged with the PMOS process detector 300 of FIG. 3.

The analog MUX circuitry of FIG. 6 may be used to allow a single error amplifier (e.g. error amplifier 700 in FIG. 7) for process detection of multiple devices using V_{GS} comparison. In particular, the MUX of FIG. 6 allows many devices to be tested and so process detection circuitry works for both NMOS and PMOS devices in the example of FIGS. 4-7. The VGS_N 602 and VGS_P 604 are from the VGS_N and VGS_P of the NMOS process detector 400 and the PMOS process detector 500, respectively. Likewise, the output VGS_N_R 606 is shown as VGS_N_R 404 with the NMOS process detector 400, and VGS_P_R 608 is shown as VGS_P_R 504 with the PMOS process detector 500.

The error amplifier 700 in FIG. 7 receives process detection from multiple devices through the analog MUX circuitry of FIG. 6. The Vin_M 610 from the MUX is shown as Vin_M 702 of the error amplifier 700 of FIG. 7. Likewise, the Vin_P 612 from the MUX is shown as Vin_P 704 of the error amplifier 700 of FIG. 7. The output 706 of the error amplifier is shown as the Out_N signal.

FIG. 8 is an illustration of NMOS process detection in different corners and FIG. 9 is an illustration of PMOS process detection in different corners. In particular, FIG. 8 is a Monte-Carlo statistical simulation of V(PDET_Out_N) from FIG. 2 and FIG. 9 is a Monte-Carlo statistical simulation of V(PDET_Out_P) from FIG. 3.

In semiconductor manufacturing, process information may include a variation of fabrication parameters used in applying an IC design to a semiconductor wafer. Process corners represent the extremes of these parameter variations within which a circuit that has been etched onto the wafer must function correctly. A circuit running on devices fabricated at these process corners may run slower or faster than specified and at lower or higher temperatures and voltages. As discussed with respect to FIG. 1, a PVT detector may detect for process, voltage, and/or temperature. As discussed herein, the process for the PVT detector includes an analysis of the corners of the process information. In particular, a corner may be a lot of semiconductors that are manufactured with extreme process parameters.

The process corners may use two-letter designators, where the first letter refers to the NMOS corner, and the second letter refers to the PMOS corner. There are at least three conditions for each device, including typical, fast and slow. Fast and slow corners exhibit carrier mobilities that are higher and lower than normal, respectively. The corners illustrated in FIGS. 8-9 are typical-typical (TT), fast-fast (FF), and slow-slow (SS).

As shown, the process detection circuit is able to generate approximately 150 mV to 200 mV variation in V(PDET_Out) for end of process corners (e.g. FF, SS) with enough separation to distinguish between them. It can be observed from FIGS. 8-9 that even with statistical variation it is possible to identify when a device is in one of the FF, TT, or SS corner.

A “computer-readable medium,” “machine readable medium,” “propagated-signal” medium, and/or “signal-bearing medium” may comprise any device that includes, stores, communicates, propagates, or transports software for use by or in connection with an instruction executable system, apparatus, or device. The machine-readable medium may selectively be, but not limited to, an electronic, magnetic, optical, electromagnetic, infrared, or semiconductor system, apparatus, device, or propagation medium. A non-exhaustive list of examples of a machine-readable medium would include: an electrical connection “electronic” having one or more wires, a portable magnetic or optical disk, a volatile memory such as a Random Access Memory “RAM”, a Read-Only Memory “ROM”, an Erasable Programmable Read-Only Memory (EPROM or Flash memory), or an optical fiber. A machine-readable medium may also include a tangible medium upon which software is printed, as the software may be electronically stored as an image or in another format (e.g., through an optical scan), then compiled, and/or interpreted or otherwise processed. The processed medium may then be stored in a computer and/or machine memory.

In an alternative embodiment, dedicated hardware implementations, such as application specific integrated circuits, programmable logic arrays and other hardware devices, can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

We claim:

1. A circuit for process detection comprising:
a first arm including a device under test subject to a first current;
a second arm with a first resistor and subject to a second current; and
a third arm including an output, second resistor, and subject to a third current;
wherein a voltage at the device under test is translated to a voltage for the output to identify process variations.

2. The circuit of claim 1 further comprising an analog-to-digital converter for detecting variations in the voltage at the output.

3. The circuit of claim 2 wherein the analog-to-digital converter provides the translation to the voltage for the output.

4. The circuit of claim 3 wherein the translation comprises an analysis of the voltage of the output in terms of digital coding

5. The circuit of claim 4 wherein the analysis of the voltage identifies a process corner, such as fast fast (FF), typical typical (TT), or slow slow (SS).

6. The circuit of claim 1 further comprising an error amplifier for maintaining the voltage at the device and voltage at the output same.

7. The circuit of claim 6 further comprising a multiplexer for providing multiple inputs to the error amplifier.

8. The circuit of claim 6 wherein the error amplifier maintains the first current, the second current, and the third current.

9. The circuit of claim 8 further comprising one or more cascode mirror structures for ensuring that the first current is equal to the second current and is equal to the third current.

10. The circuit of claim 9 further comprising a multiplexor for providing multiple inputs to the error amplifier.

11. A circuit comprising:
a device under test with a first arm;
an amplifier with a first voltage at the device under test and a second voltage at a second arm that includes a first resistor; and
an output arm with a second resistor that includes an output voltage.

12. The circuit of claim 11 further comprising an analog-to-digital converter for detecting variations in the voltage at the output.

13. The circuit of claim 12 wherein the ADC provides a translation of the output voltage.

14. The circuit of claim 13 wherein the translation comprises an analysis of the output voltage in terms of digital coding.

15. The circuit of claim 14 wherein an analysis of the voltage identifies a process corner, such as fast fast (FF), typical typical (TT), or slow slow (SS).

16. The circuit of claim 11 further comprising an error amplifier for maintaining the voltage at the device and voltage at the output same.

17. The circuit of claim 16 wherein the error amplifier maintains the first current, the second current, and the third current.

18. The circuit of claim 11 further comprising a multiplexer for providing multiple inputs to the error amplifier.

19. A method for identifying process variations in a circuit that includes a device under test, the method comprising:
establishing a gate source voltage at the device under test at a first arm;
comparing voltage at a second arm with a resistor with the gate source voltage of the first arm;
establishing the output voltage at a third arm with a resistor; and
identifying process variations based on the comparing and nullifying process variations of the resistors.

20. The method of claim 19 wherein the comparison and digitization comprises:
determining the process corner information based on output voltage and the gate source voltage.
